(19) United States
(12) Patent Application Publication
(10) Pub. No.: US 2025/0336790 A1
(43) Pub. Date: Oct. 30, 2025

(54) Semiconductor Device and Method of Making a Wafer-Level Substrate

(71) Applicant: STATS ChipPAC Pte. Ltd., Singapore (SG)

(72) Inventors: Swain Hong Alfred Yeo, Singapore (SG); Kai Chong Chan, Singapore (SG); Linda Pei Ee Chua, Singapore (SG); Yaojian Lin, Jiangyin (CN)

(73) Assignee: STATS ChipPAC Pte. Ltd., Singapore (SG)

(21) Appl. No.: 18/646,629

(22) Filed: Apr. 25, 2024

(51) Int. Cl. H01L 23/498; H01L 21/48; H01L 21/56; H01L 23/00; H01L 23/31; H01L 23/64; H01L 25/16

(52) U.S. Cl. CPC H01L 23/49838; H01L 21/4853; H01L 21/4857; H01L 21/561; H01L 21/565; H01L 23/3135; H01L 23/49811; H01L 23/49822; H01L 23/642; H01L 24/16; H01L 24/81; H01L 24/96; H01L 24/97; H01L 25/16; H01L 2224/16227; H01L 2224/81815; H01L 2224/96; H01L 2224/97; H01L 2924/19011; H01L 2924/19041

(57) ABSTRACT

A semiconductor device has an e-bar and an encapsulant deposited over the e-bar. A first surface of the encapsulant is backgrinded to expose the e-bar. A first build-up interconnect structure is formed over the first surface of the encapsulant. A second build-up interconnect structure is formed over a second surface of the encapsulant.

### FIELD OF THE INVENTION

The present invention relates in general to semiconductor devices and, more particularly, to a semiconductor device and method of making a wafer-level substrate.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor device manufacturers are continually striving to make smaller semiconductor devices to meet the demands of electronic device manufacturers and consumers alike. At the same time, more and more complex semiconductor devices are demanded by device manufacturers. Therefore, a need exists for a semiconductor device and method of making a wafer-level substrate.

### BRIEF DESCRIPTION OF THE DRAWINGS

FIGS. 1a-1c illustrate a semiconductor wafer with a plurality of semiconductor die separated by a saw street;

FIGS. 2a-2g illustrate forming a wafer-level substrate;

FIGS. 3a-3d illustrate forming a semiconductor package with the wafer-level substrate;

FIGS. 4a-4f illustrate a wafer-level substrate with alternative types of e-bars; and

FIGS. 5a and 5b illustrate an electronic device with the semiconductor package.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

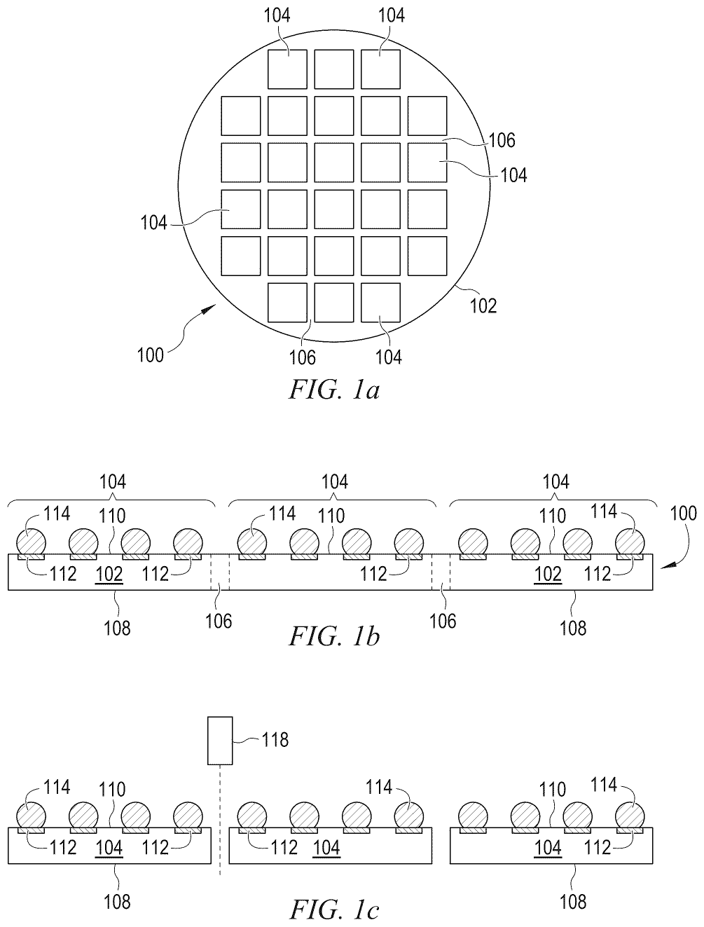

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as a digital signal processor (DSP), application specific integrated circuit (ASIC), memory, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating, sputtering, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under-bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or unit after singulation.

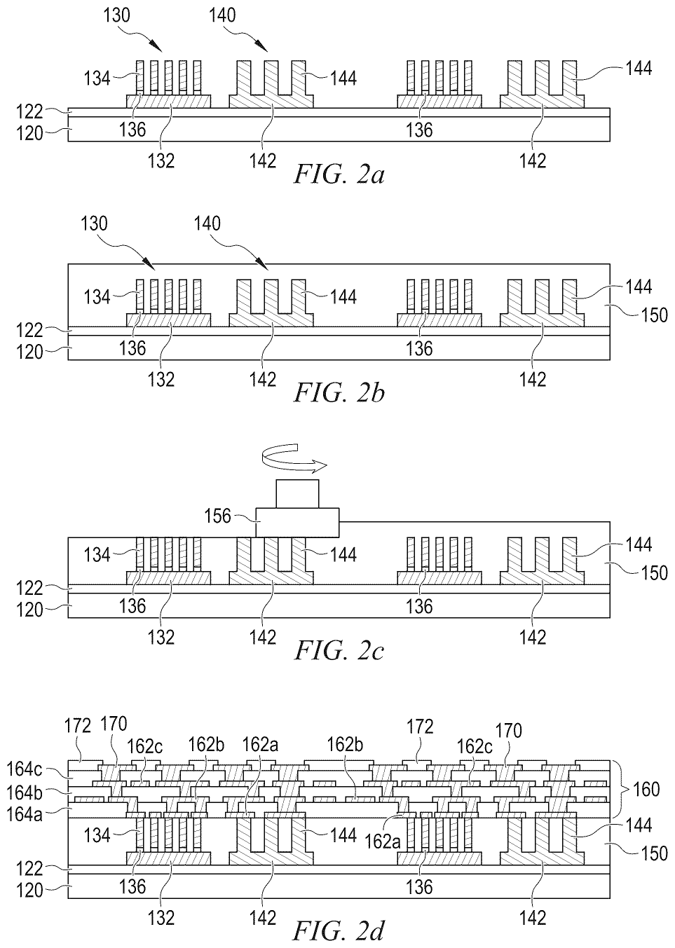

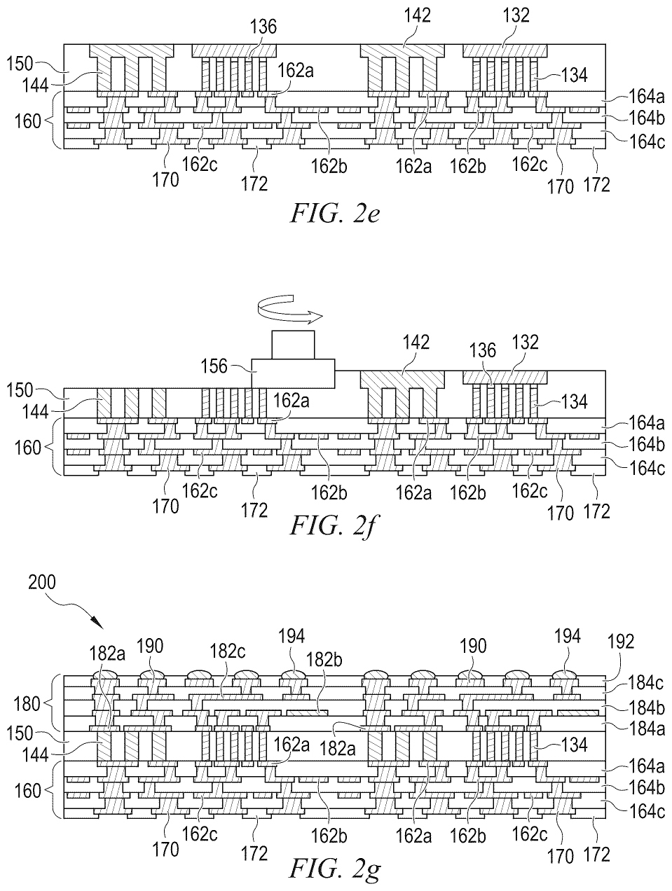

FIGS. 2a-2g illustrate the formation of a wafer-level substrate. In FIG. 2a, formation of the substrate begins using a temporary substrate or carrier 120 with double-sided tape or interface layer 122. Carrier 120 contains sacrificial base material such as silicon, polymer, beryllium oxide, glass, or other suitable low-cost, rigid material for structural support. An interface layer or double-sided tape 122 is formed or disposed over carrier 120 as a temporary adhesive bonding film, etch-stop layer, thermal release layer, or UV release layer.

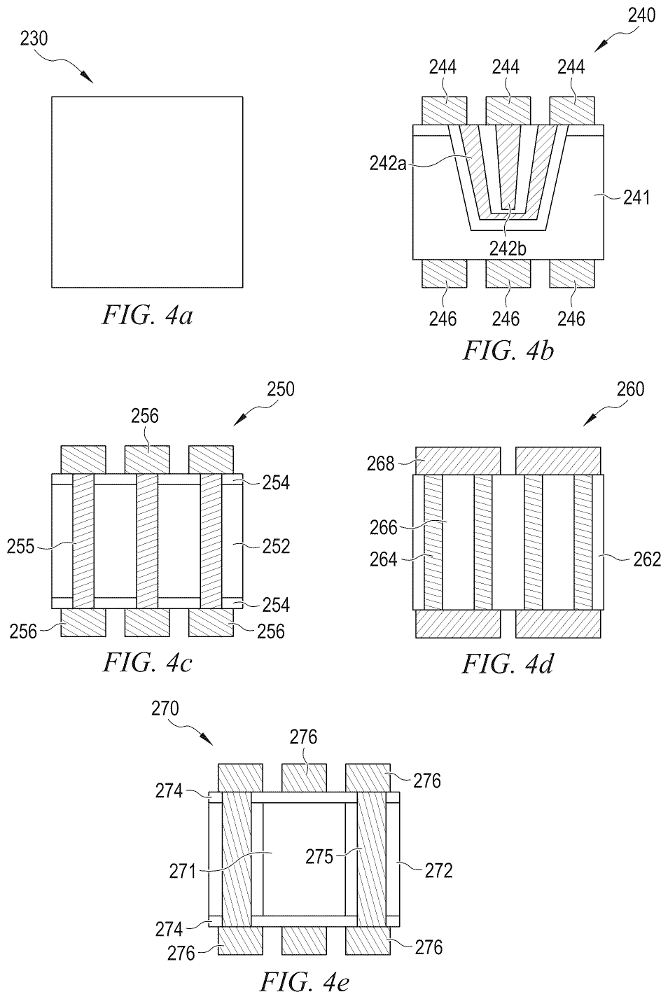

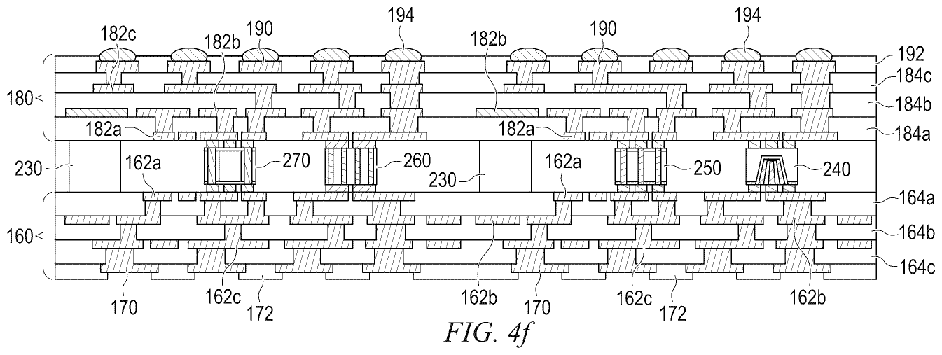

A plurality of e-bars is disposed on carrier 120 and will be embedded in the substrate being formed. The embedded bars (e-bars) can come with a wide variety of structural and functional features. The ‘e’ portion of the term e-bar means that the bar will be embedded within a substrate or other similar device. The ‘bar’ portion of the term e-bar refers to the e-bar's shape being as a bar because e-bars are typically elongated along a substantial majority of a length or width dimension of a substrate or semiconductor package, e.g., at least eighty percent. E-bars are also typically pre-formed prior to them being embedded, so the individual e-bars look like bars that are disposed onto carrier 120. FIGS. 4a-4e illustrate a number of alternative e-bar options to those shown in FIG. 2a.

E-bars 130 include a base 132 and a plurality of conductive pillars 134 attached to the base with solder 136. E-bars 140 include a base 142 and a plurality of conductive pillars 144 extending directly from the base as part of a single continuous block of material. In one embodiment, a height of pillars 134 and 144 is 200 μm or greater.

E-bars 130 are formed by soldering conductive pillars 134 onto base 132, while e-bars 140 are formed by etching base 142 and pillars 144 from a block of material. Alternatively, e-bars 140 without solder can be formed by deposition of conductive material onto a base 142 through mask openings. Both are shown to provide multiple examples, but generally all e-bars with conductive pillars extending from a base in a single substrate would be formed using a common manufacturing method. In other embodiments, conductive pillars can be formed individually and disposed directly on carrier 120 without a base.

Base 132 and conductive pillars 134 can be formed of any suitable electrically conductive material, e.g., copper, gold, silver, steel, aluminum, combinations thereof, or alloys thereof. Base 132 can be a non-conductive material in some embodiments. Base 132 is a sheet of material formed by rolling, molding, cutting, or another suitable process. In one embodiment, a plurality of e-bars 130 is formed on a large sheet of base 132 and then singulated from each other after conductive pillars 134 are attached.

Conductive pillars 134 are formed by cutting them from a block of material, by depositing material into a mask opening, by molding, or by another suitable process. In one embodiment, conductive pillars 134 are formed before a pick and place machine dips the conductive pillars in solder and then disposes them on base 132. The solder 136 for each conductive pillar 134 is reflowed at the same time to physically attach the conductive pillars to base 132. A conductive or non-conductive adhesive or epoxy is used instead of solder in some embodiments.

E-bars 140 are formed from a block of material by removing some of the material, leaving pillars 144 extending from base 142. E-bars 140 can be formed by chemical etching, CNC milling, laser ablation, or another suitable method. E-bars 140 are typically formed from a large sheet of conductive material and then singulated into individual e-bar units. The material for e-bars 140 can be the same materials discussed above for conductive pillars 134.

Both e-bars 130 and 140 are disposed onto carrier 120 with pillars 134 and 144, respectively, extending upward away from the carrier. E-bars 130 and 140 can each be formed with any desired number and layout of conductive pillars as required for signal routing of the semiconductor packages eventually being formed with the substrates. Any number and layout of e-bars and conductive pillars can be used to form a wafer-level substrate with the desired signal routing, including combining other types of e-bars with e-bars 130 or 140.

In FIG. 2b, encapsulant or molding compound 150 is deposited over and around carrier 120, e-bars 130, and e-bars 140 using a paste printing, compressive molding, transfer molding, liquid encapsulant molding, vacuum lamination, spin coating, or another suitable applicator. Encapsulant 150 can be liquid or granular polymer composite material, such as epoxy resin, epoxy acrylate, or polymer, with or without an added filler. In another embodiment, encapsulant 150 is a laminated mold sheet or film with or without fillers. Encapsulant 150 is non-conductive, provides structural support, and environmentally protects e-bars from external elements and contaminants. Encapsulant 150 can also be any of the materials and formed using any of the methods discussed below for insulating layers generally. Encapsulant 150 is a sheet of prepreg in one embodiment.

Encapsulant 150 completely covers the previously exposed outer surfaces of conductive pillars 134 and 144. In other embodiments, encapsulant 150 is deposited to have the tops of conductive pillars 134 and 144 exposed from or coplanar to the top surface of the encapsulant, e.g., using film-assisted molding. In FIG. 2c, encapsulant 150 is backgrinded using a grinder 156 to expose conductive pillars 134 and 144 if not already exposed by the molding process. Portions of pillars 134 and 144 are removed by grinder 156 in some embodiments to ensure the pillars are exposed and coplanar.

In FIG. 2d, a build-up interconnect structure 160 is formed over encapsulant 150. Interconnect structure 160 being called a build-up interconnect structure refers to the way that the interconnect structure is formed by successively building up insulating layers and conductive layers over encapsulant 150 until the desired signal routing is achieved.

Forming interconnect structure 160 starts by forming a conductive layer 162a on encapsulant 150 and the exposed tops of conductive pillars 134 and 144. Conductive layer 162a includes conductive traces to fan-out from conductive pillars 134 and 144 and, optionally, contact pads at both ends of the traces for connecting to the underlying conductive pillars and for subsequent formation of overlying conductive vias. Conductive layer 162a is formed using any of the methods and materials described above for conductive layer 112. Any suitable conductive layer deposition and patterning method can be used in other embodiments, e.g., using an additive or subtractive process. Any conductive layer mentioned above or below can be formed as described for conductive layers 162a and 112. In some embodiments, an insulating or passivation layer is formed first on encapsulant 150, and then conductive layer 162a is formed.

An insulating layer 164a is formed over conductive layer 162a. Insulating layer 164a contains one or more layers of silicon dioxide (SiO2), silicon nitride (Si3N4), silicon oxynitride (SiON), tantalum pentoxide (Ta2O5), aluminum oxide (Al2O3), solder resist, polyimide (PI), photosensitive polyimide (PSPI) benzocyclobutene (BCB), polybenzoxazoles (PBO), and other material having similar insulating and structural properties. Insulating layer 164a can be formed using PVD, CVD, printing, lamination, spin coating, spray coating, sintering, or thermal oxidation. Any insulating, passivation, or dielectric layer mentioned above or below can be formed using any of the materials or methods described for insulating layer 164a.

Openings are formed through passivation layer 164a to expose contact pads of the underlying conductive layer 162a. The openings can be formed by chemical etching, photolithography, mechanical drilling, laser drilling, or any other suitable means. Additional conductive layers 162 and insulating layers 164 are interleaved over encapsulant 150 as needed to implement the desired electrical signal routing. In the illustrated embodiments, three conductive layers 162a, 162b, and 162c are formed for signal routing with three insulating layers 164a, 164b, and 164c formed over the conductive layers, respectively. Each successive conductive layer 162 is formed through openings of an underlying insulating layer 164 to electrically connect vertically through build-up interconnect structure 160. Any suitable number of insulating and conductive layers, including less than three, can be used to implement the desired signal routing.

After the desired number of conductive layers 162 and insulating layers 164 have been built up, contact pads or under-bump metallization (UBM) pads 170 are formed on the top conductive layer 162c through openings in the top insulating layer 164c. UBM pads 170 include conductive vias or otherwise extend through insulating layer 164c to physically and electrically contact the underlying conductive layer 162c. In some embodiments, UBM pads 170 are formed of multiple conductive layers including a wetting layer, barrier layer, and adhesion layer. UBM pads 170 can have a flat top surface as illustrated or be formed conformally in the openings of the top insulating layer 164.

A passivation or solder resist layer 172 is formed over UBM pads 170. Passivation layer 172 is formed of materials using methods as described above for insulating layers generally. Openings are formed in passivation layer 172 to expose UBM pads 170 for subsequent electrical interconnect.

In FIG. 2e, carrier 120 is removed from encapsulant 150 using thermal, laser, UV, or other energy to reduce adhesion of interface layer 122. The panel of encapsulant 150, e-bars 130 and 140, and interconnect structure 160 is flipped so bases 132 and 142 are exposed for further processing. The panel is optionally disposed back on carrier 120 or another similar carrier. Backgrinding tape is used in one embodiment.

In FIG. 2f, encapsulant 150, bases 132, and bases 142 are backgrinded using grinder 156 or another grinder, or another suitable process, e.g., chemical etching or chemical-mechanical planarization (CMP), to completely remove the bases of each e-bar 130 and 140. The removal of bases 132 and 142 electrically isolates conductive pillars 134 and 144 from each other and leaves the conductive pillars as conductive vias extending through encapsulant 150. Backgrinding a portion of the e-bars is not necessary in all embodiments, due to some e-bars having conductive vias or contact pads that are already electrically isolated and without a base designed to be removed.

In FIG. 2g, a second build-up interconnect structure 180 is formed in the same or a similar manner as described above for build-up interconnect structure 160, but on the opposite side of encapsulant 150. Build-up interconnect structure 180 includes a plurality of conductive layers 182a-182c interleaved with a plurality of insulating layers 184a-184c. More or less than three RDL layers can be formed. The number of RDL layers can be the same or different between build-up interconnect structures 160 and 180.

A plurality of UBM pads 190 is formed over the top conductive layer 182c and insulating layer 184c as described above for UBM pads 170. A passivation or solder layer 192 is formed over UBM pads 190 as described above for passivation layer 172. Solder bumps 194 are disposed or formed on UBM pads 190 as described above for bumps 114. Bumps 194 are stencil printed in one embodiment. Solder bumps are optionally formed on UBM pads 170 instead of or in addition to solder bumps 194 on UBM pads 190.

FIG. 2g shows a completed wafer-level substrate 200. Substrate 200 is a semiconductor package substrate formed at the wafer-level, i.e., being large enough to form a plurality of semiconductor packages on a single substrate prior to singulation. All manufacturing for substrate 200 can be processed at the strip, wafer, or panel level. UBM pads 170 are coupled to UBM pads 190 through conductive layers 162, conductive pillars 134 and 144, and conductive layers 182. Conductive layers 162 and 182 distribute electrical signals as needed for the electrical devices to be coupled on each side of substrate 200. Conductive pillars 134 and 144 provide the primary vertical interconnect for signals, power, and ground through substrate 200. The manufacturing method shown for substrate 200 is cost-effective over conventional laminate substrate fabrication while still using the same existing manufacturing technology. In some embodiments, substrate 200 is the final product as manufactured and sold by a substrate manufacturing company. Substrate 200 is purchased by a semiconductor package manufacturing company to form semiconductor packages with the substrate.

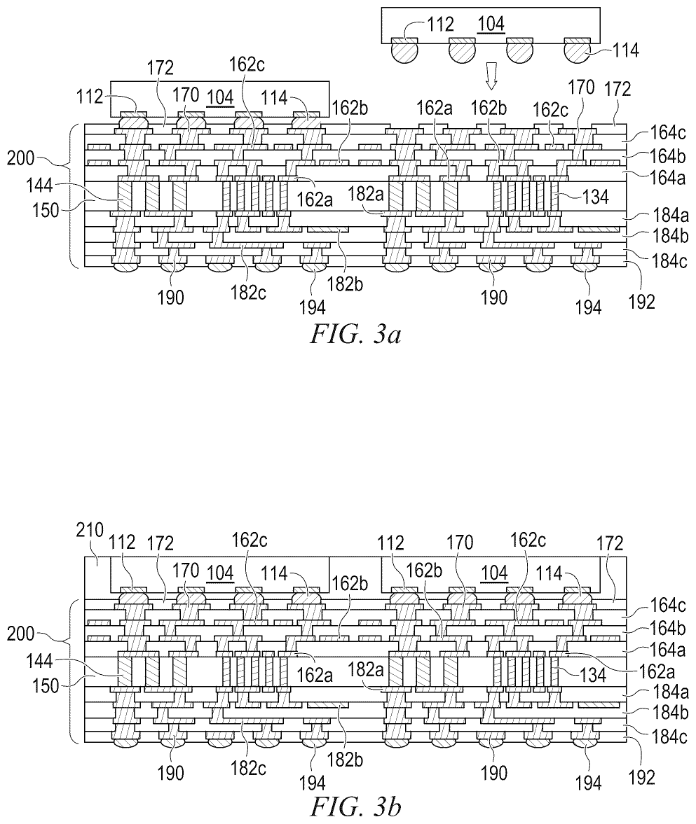

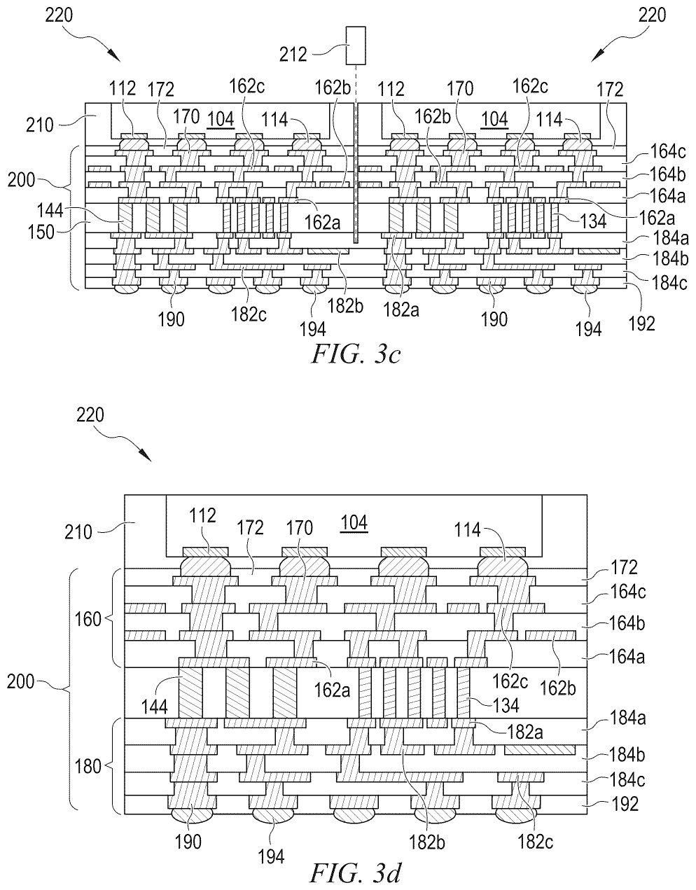

Substrate 200 can then be used to form semiconductor packages using any suitable method. Only one of many such possible methods is illustrated in FIGS. 3a-3d. In FIG. 3a, semiconductor die 104 are mounted onto substrate 200 with solder bumps 114 oriented toward the substrate. Semiconductor die 104 are picked and placed onto substrate 200, and then bumps 114 are reflowed to mechanically and electrically connect the semiconductor die to the substrate via UBM pads 170.

Two packages with one semiconductor die 104 each are being formed, but many more packages are typically formed at once using a single substrate. The semiconductor packages being formed can also include more than one semiconductor die or any other suitable electronic components, e.g., discrete active or passive electrical components.

An encapsulant 210 is deposited over, around, and under semiconductor die 104 in FIG. 3b. Encapsulant 210 can be deposited using any of the methods and materials described above for encapsulant 150. Encapsulant 210 can be backgrinded or deposited with film-assisted molding to make the back surfaces of the semiconductor die coplanar to encapsulant 210. In other embodiments, encapsulant 210 is left completely covering semiconductor die 104. An underfill is optionally used between semiconductor die 104 and substrate 200 in addition to or instead of encapsulant 210.

Substrate 200 and encapsulant 210 are singulated in FIG. 3c using a saw blade or laser cutting tool 212 to separate semiconductor packages 220. FIG. 3d shows a completed semiconductor package 220. Semiconductor die 104 is electrically coupled to bumps 194 by UBM pads 170, conductive layers 164a-164c, conductive pillars 134 and 144, conductive layers 184a-184c, and UBM pads 190.

FIGS. 4a-4f illustrate other types of e-bars used to form a substrate instead of, or in addition to, e-bars 130 or 140. FIG. 4a shows an e-bar 230 that is simply a blank silicon (Si) bar. E-bar 230 has no electrical function but can be used as filler in a substrate core, to balance warpage of the substrate, or for other purposes.

E-bar 240 in FIG. 4b has Si bar 241 with a deep trench capacitor (DTC) 242 formed in the Si bar. DTC 242 is formed of two capacitor plates 242a and 242b connected to contact pads 244. In one embodiment, a plurality of capacitor plates 242a and 242b is connected to contact pads 244 to increase the capacitance density. Contact pads 246 on the bottom of e-bar 240 are optional, and can be dummy pads for symmetry, connected to pads 244 by conductive vias, connected to other electrical circuits formed on e-bar 240, or used as a bridge to connect two other components together.

E-bar 250 in FIG. 4c is a through-glass via (TGV) glass bar with optional integrated passive devices and other discrete circuits. E-bar 250 includes a glass core 252 with optional polyimide or polymer matrix dielectric/composite layers 254 formed on the top and bottom surfaces of the glass core. TGV 255 are formed through glass core 252 to provide electrical connection between contact pads 256 on the top and bottom of e-bar 250.

E-bar 260 in FIG. 4d is a PCB/substrate bar with low coefficient of thermal expansion (CTE) and high modulus. E-bar 260 has a core 262 formed of insulating PCB or substrate material, e.g., FR-4 or another suitable material. Conductive vias 264 are formed through core 262. Vias 264 comprise a conductive coating around the outside of an opening. The opening is then filled with a material 266 as a core for conductive vias 264. Contact pads 268 are formed on the top and bottom of core 262 to electrically couple to vias 264.

E-bar 270 in FIG. 4e is a hybrid bar that includes a magnetic bar core 271. An encapsulant or other material 272 is deposited around magnetic bar 271. An optional polyimide or polymer matrix dielectric/composite layer 274 is formed over the top and bottom of encapsulant 272 and magnetic bar 271. Conductive vias 275 are formed through encapsulant 272. Conductive layer 276 is formed over the top and bottom surfaces of core 272. In some embodiments, conductive vias 275 and conductive layer 276 form a coil around magnetic bar 271 to form an inductor. Conductive layer 276 also forms contact pads for external electrical connection.

FIG. 4f shows a substrate 280 with e-bars 230, 240, 250, 260, and 270 embedded within encapsulant 150. Other than the use of a variety of e-bars, manufacture of substrate 280 proceeds the same as substrate 200, e.g., by forming interconnect structures 160 and 180 over the two major surfaces of encapsulant 150. Substrate 280 can be used as a package substrate for forming any type of semiconductor package as with substrate 200.

E-bars 230, 240, 250, 260, and 270 do not need backgrinding due to having contact pads on their external surfaces instead of a removable base. If used in conjunction with e-bars 130 or 140, e-bars 230, 240, 250, 260, or 270 can be placed on a conductive layer to allow the backgrinding of bases 132 or 142 without removing part of the other e-bars. Alternatively, a base can be added to the e-bars in FIGS. 3a-3e, their contact pads can be formed thicker so that a portion can be removed with bases 132 or 142, or a bottom portion of the e-bars can be removed if the lower surface is non-functional.

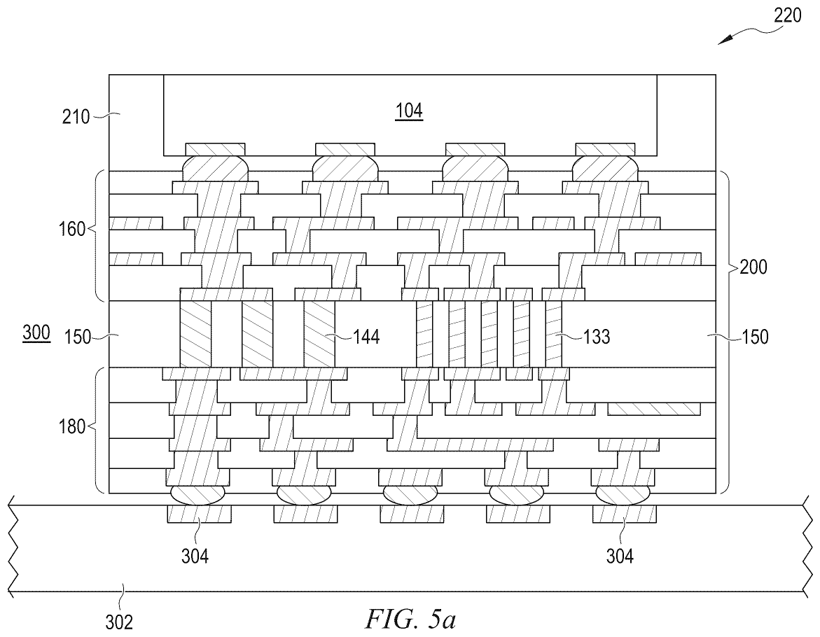

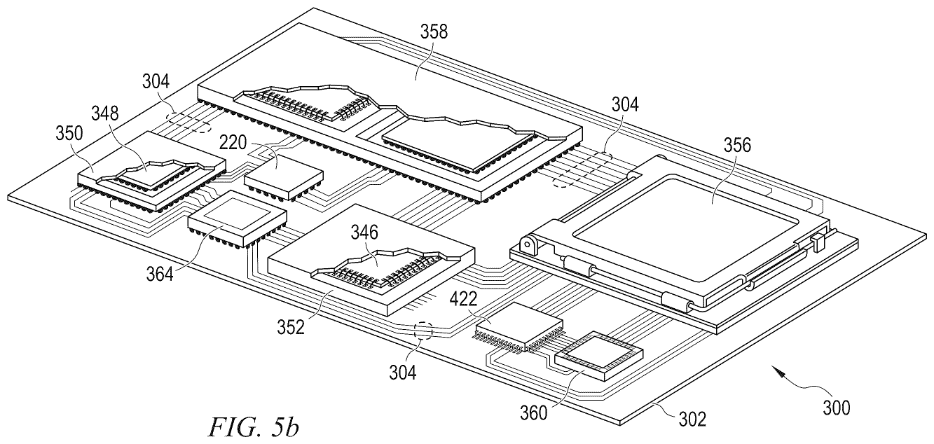

FIGS. 5a and 5b illustrate integrating the above-described semiconductor packages, e.g., semiconductor package 220, into a larger electronic device 300. FIG. 5a illustrates a partial cross-section of semiconductor package 220 mounted onto a printed circuit board (PCB) or other substrate 302 as part of electronic device 300. Solder bumps 194 are reflowed onto conductive layer 304 of PCB 302 to physically attach and electrically connect semiconductor package 220 to the PCB. In other embodiments, thermocompression or another suitable attachment and connection methods are used. In some embodiments, an adhesive or underfill layer is used between semiconductor package 220 and PCB 302. Semiconductor die 104 is electrically coupled to conductive layer 304 through substrate 200.

FIG. 5b illustrates electronic device 300 having a chip carrier substrate or PCB 302 with a plurality of semiconductor packages disposed on a surface of PCB 302, including semiconductor package 220. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 5b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, which lowers costs up and down the supply chain.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing an e-bar;
depositing an encapsulant over the e-bar;
backgrinding a first surface of the encapsulant to expose the e-bar;
forming a first build-up interconnect structure over the first surface of the encapsulant; and
forming a second build-up interconnect structure over a second surface of the encapsulant.

2. The method of claim 1, further including providing the e-bar to include a base and a plurality of conductive pillars extending from the base.

3. The method of claim 2, further including backgrinding the second surface of the encapsulant to remove the base.

4. The method of claim 1, wherein the e-bar includes a core and a conductive via extending through the core.

5. The method of claim 1, wherein the e-bar includes a passive electrical component.

6. The method of claim 1, further including mounting a semiconductor die on the first build-up interconnect structure or second build-up interconnect structure.

7. A method of making a semiconductor device, comprising:
providing an e-bar;
depositing an encapsulant over the e-bar;
backgrinding the encapsulant to expose the e-bar; and
forming a build-up interconnect structure over the encapsulant and e-bar.

8. The method of claim 7, further including providing the e-bar to include a base and a plurality of conductive pillars extending from the base.

9. The method of claim 8, further including backgrinding the encapsulant to remove the base.

10. The method of claim 7, wherein the e-bar includes a core and a conductive via extending through the core.

11. The method of claim 7, wherein the e-bar includes a passive electrical component.

12. The method of claim 7, further including mounting a semiconductor die on the build-up interconnect structure.

13. The method of claim 12, further including:
depositing an underfill or second encapsulant between the semiconductor die and build-up interconnect structure; and
singulating the underfill or second encapsulant, build-up interconnect structure, and encapsulant to form a semiconductor package.

14. A method of making a semiconductor device, comprising:
providing an e-bar;
depositing an encapsulant over the e-bar; and
forming a build-up interconnect structure over the encapsulant and e-bar.

15. The method of claim 14, further including providing the e-bar to include a base and a plurality of conductive pillars extending from the base.

16. The method of claim 15, further including backgrinding the encapsulant to remove the base.

17. The method of claim 14, wherein the e-bar includes a core and a conductive via extending through the core.

18. The method of claim 14, wherein the e-bar includes a passive electrical component.

19. The method of claim 14, further including mounting a semiconductor die on the build-up interconnect structure.

20. A semiconductor device, comprising:
an e-bar;
an encapsulant deposited over the e-bar; and
a build-up interconnect structure formed over the encapsulant and e-bar.

21. The semiconductor device of claim 20, wherein the e-bar includes a plurality of conductive pillars.

22. The semiconductor device of claim 20, wherein the e-bar includes a core and a conductive via extending through the core.

23. The semiconductor device of claim 20, wherein the e-bar includes a passive electrical component.

24. The semiconductor device of claim 20, further including a semiconductor die mounted on the build-up interconnect structure.

25. The semiconductor device of claim 24, further including an underfill disposed between the semiconductor die and build-up interconnect structure.
